(19) United States
(12) Patent Application Publication
(10) Pub. No.: US 2014/0340083 A1
(43) Pub. Date: Nov. 20, 2014

(54) Parallel acquisition image reconstruction method and device for magnetic resonance imaging

(71) Applicant: Shanghai United Imaging Healthcare Co., Ltd., Shanghai (CN)

(72) Inventors: Weiguo Zhang, Shanghai (CN); Qiang Zhang, Shanghai (CN); Renkuan Zhai, Shanghai (CN)

(73) Assignee: Shanghai United Imaging Healthcare Co., Ltd., Shanghai (CN)

(21) Appl. No.: 14/136,387

(22) Filed: Dec. 20, 2013

(30) Foreign Application Priority Data
May 17, 2013 (CN) 201310185159.0

(51) Int. Cl. G01R 33/561

(52) U.S. Cl. CPC G01R 33/5612
USPC 324/309; 324/318

(57) ABSTRACT

A method and a parallel acquisition image reconstruction device for magnetic resonance imaging are provided. The method may include: sampling magnetic resonance signals from a plurality of channels, and filling the magnetic resonance signals in an initial k-space; obtaining a first virtual space by performing a mathematical transformation, and obtaining a second virtual space by reserving virtual channels of the first virtual space; calculating a first combination coefficient, and a second combination coefficient; putting the first combination coefficient and the second combination coefficient into a predetermined objective function to obtain the data of the second virtual space; and transforming the data of the second virtual space to an image domain to obtain a reconstructed image. The method of the present disclosure reserves data of channels having a high signal-to-noise ratio to serve as the second virtual space, whereby the image reconstruction speed and signal-to-noise ratio of image are improved.

### CROSS-REFERENCE TO RELATED APPLICATIONS

The present application claims priority to Chinese patent application No. 201310185159.0, filed on May 17, 2013, and entitled “PARALLEL ACQUISITION IMAGE RECONSTRUCTION METHOD AND DEVICE FOR MAGNETIC RESONANCE IMAGING”, the entire disclosure of which is incorporated herein by reference.

### TECHNICAL FIELD

The present disclosure generally relates to Magnetic Resonance Imaging (MRI) technology, and more particularly, to a parallel acquisition image reconstruction method and a parallel acquisition image reconstruction device for magnetic resonance imaging.

### BACKGROUND

Medical MRI is an imaging technology using characteristics of magnetic sensitive nuclei (proton nuclei) of human body in a magnetic field. In MRI technology, imaging speed is an important criterion to evaluate an imaging method. So far, methods for improving MRI speed can be classified into three categories: first, improving performance of hardware; second, improving scanning technology in k-space; and third, partial k-space data imaging. In MRI technology, magnetic resonance signal space (original data space) is known as k-space, which is also known as Fourier transformation space. Signal data sampled in k-space is processed by inverse Fourier transform and magnitude calculation, in order to obtain a magnetic resonance magnitude image. Partial k-space data acquisition and reconstruction is an imaging technology which just samples a part of k-space data, so that the scanning speed can be substantially increased without hardware and other additional changes.

Data sampling and k-space filling are important factors that limit the speed of MRI data acquisition. Techniques of parallel acquisition image reconstruction for magnetic resonance imaging fill partially the k-space data with a coil reconstruction-merger method using multi-channel phased array coils, so as to obtain full k-space data from the partially sampled k-space data for image reconstruction. In this way, only part of the k-space data is actually sampled, leading to increased imaging speed.

Generalized Auto-calibrating Partially Parallel Acquisitions (GRAPPA) is a commonly used parallel acquisition image reconstruction method. A conventional GPAPPA method is shown in FIG. 1. Sampled signals are represented by frequency- and phase-encoding in k-space. As shown in FIG. 1, the horizontal direction represents phase encoding direction, the vertical direction represents channel number, and the direction perpendicular to the paper surface represents frequency encoding direction. Solid black points 101 represent actually sampled k-space data, empty white points 102 represents un-sampled data which needs to be filled, and solid gray points 103 represent a part of all sampled data selected for calculating combination coefficients. In GPAPPA algorithm, any one of the empty white points 102 can be represented by a linear superposition of the surrounding solid black points 101, which is equivalent to a combination of data from a plurality of coils. As shown in FIG. 1, a combination coefficient nᵢⱼ corresponding to the i^{th} coil and the j^{th} position in k-space, can be determined by fitting the solid gray points 103 with the solid black points 101. After the combination coefficient are determined, the un-sampled data represented by the empty white points 102 can be filled with a combination of sampled data from the plurality of coils based on the combination coefficient.

Recently, an Iterative Self-consistent Parallel Imaging Reconstruction from Arbitrary k-Space (SPIRiT) method is provided. The SPIRiT method reconstructs images in an iterative manner, and has a better reconstruction result than the GRAPPA method. As shown in FIGS. 2(a) and 2(b), empty white points 201 represent un-sampled data, solid black points 202 represent sampled data, and a dashed box 203 represents a convolution kernel. In the SPIRiT method, any point, no matter sampled or un-sampled, can be obtained by fitting the surrounding points. On the contrary, only the un-sampled points are obtained from fitting the sampled data in the GRAPPA method. Shown in FIGS. 2(a) and 2(b) is one channel data distribution to facilitate the description. Data distributions of other channels are omitted for reason of simplicity.

However, a large number of channels are required in the parallel acquisition process to obtain a better imaging result, but reconstruction speed is reduced when the number of channel is large. Meanwhile, because some channels may have poor signal-to-noise ratios, the signal-to-noise ratio of the final image can be reduced if data of all channels are combined. In a word, the conventional method can result in low reconstruction speed and non-optimal signal-to-noise ratio.

Therefore, a parallel acquisition image reconstruction method for magnetic resonance imaging, which can improve image reconstruction speed and signal-to-noise ratio, is needed.

### SUMMARY

The present disclosure aims to solve the problems of a low image reconstruction speed and a low signal-to-noise ratio image of the conventional parallel acquisition image reconstruction method for magnetic resonance imaging.

In order to solve the problems mentioned above, a parallel acquisition image reconstruction method for magnetic resonance imaging is provided in the present disclosure. The method includes:

sampling magnetic resonance signals from a plurality of channels, and filling the magnetic resonance signals in an initial k-space, where the initial k-space includes a fully-sampled area and an under-sampled area, each data point in the fully-sampled area is sampled, and the under-sampled area includes sampled data points and un-sampled data points;

obtaining a first virtual space by performing a mathematical transformation on the initial k-space, where the first virtual space comprises a plurality of virtual channels each having a first parameter for evaluating signal-to-noise ratio, and obtaining a second virtual space by reserving virtual channels of the first virtual space which have first parameters higher than a predetermined threshold value;

calculating a first combination coefficient from the data of the initial k-space to data of the second virtual space, and a second combination coefficient from the data of the second virtual space to the data of the initial k-space;

putting the first combination coefficient and the second combination coefficient into a predetermined objective function to obtain the data of the second virtual space; and

transforming the data of the second virtual space to an image domain to obtain a reconstructed image.

In some embodiments, the mathematical transformation includes: Wavelet transformation, Curvelet transformation or Karhunen-Loeve (KL) transformation.

In some embodiments, the Karhunen-Loeve transformation is adopted to obtain the first virtual; data of the fully-sampled area serves as calibration data, and the first parameter is amplitude of an eigenvalue of the KL transformation of the calibration data of each channel.

In some embodiments, the first combination coefficient is a convolution kernel of a fitting operation from the initial k-space to the second virtual space of each channel, where the first combination coefficient is obtained according to an equation shown below:

Src*G=Dst,

where Src represents the data of the initial k-space of each channel, Dst represents the data of the second virtual space, and G represents the first combination coefficient;

the second combination coefficient is a convolution kernel of a fitting operation from the second virtual space to the initial k-space of each channel, where the second combination coefficient is obtained according to an equation shown below:

Dst*P=Src,

where P represents the second combination coefficient.

In some embodiments, the objective function is expressed as an equation shown below:

Val=∥GPx−x∥₂+λ·Reg(x)

where G represents the first combination coefficient, P represents the second combination coefficient, x represents the data of the second virtual space, Reg(x) represents a cost function, λ represents a coefficient of the cost function, Val represents a target value, and the data x of the second virtual space is obtained according to the objective function under a condition that the target value Val has a minimum value.

In some embodiments, the objective function is expressed as an equation shown below:

Val=∥(GP−I)(D^{T}a+D_{c}^{T}m)∥₂+λ·∥ψF^{H}(D^{T}a+D_{c}^{T}m)∥₁

where D^{T}a represents sampled data of the second virtual space, D_{c}^{T}m represents un-sampled data of the second virtual space, Ψ represents a regularization transformation matrix, F represents a Fourier transformation, Val represents a target value, the un-sampled data D_{c}^{T}m of the second virtual space is obtained according to the objective function under a condition that the target value Val has a minimum value, and the data x of the second virtual space is obtained by combining the un-sampled data D_{c}^{T}m and the sampled data D^{T}a of the second virtual space.

In some embodiments, the objective function is expressed as an equation shown below:

Val=∥(GP−I)(D^{T}a+D_{c}^{T}m)∥₂+λ·∥ψ·S·F^{H}(D^{T}a+D_{c}^{T}m)∥₁

where D^{T}a represents sampled data of the second virtual space, D_{c}^{T}m represents un-sampled data of the second virtual space, Ψ represents a regularization transformation matrix, S represents a coil sensitivity coefficient matrix, F represents a Fourier transformation, Val represents a target value, the un-sampled data D_{c}^{T}m of the second virtual space is obtained according to the objective function under a condition that the target value Val has a minimum value, and the data x of the second virtual space is obtained by combining the un-sampled data D_{c}^{T}m and the sampled data D^{T}a of the second virtual space.

In some embodiments, assuming that each data point of the second virtual space is unknown, the objective function is expressed as an equation shown below:

Val=∥(GP−I)x∥₂+λ·∥ψF^{H}x∥₁+β·∥Dx−a∥₂

where x represents the data of the second virtual space, Ψ represents a regularization transformation matrix, F represents a Fourier transformation, D represents a sampling matrix of sampled data, β represents an adjustment coefficient, Val represents a target value, and the data x of the second virtual space is obtained according to the objective function under a condition that the target value Val has a minimum value.

In some embodiments, assuming that each data point of the second virtual space is unknown, the objective function is expressed as an equation shown below:

Val=∥(GP−I)x∥₂+λ·∥ψ·S·F^{H}x∥₁+β·∥Dx−a∥₂

where x represents the data of the second virtual space, Ψ represents a regularization transformation matrix, S represents a coil sensitivity coefficient matrix, F represents a Fourier transformation, D represents a sampling matrix of sampled data, β represents an adjustment coefficient, Val represents a target value, and the data x of the second virtual space is obtained according to the objective function under a condition that the target value Val has a minimum value.

In some embodiments, if the parallel acquisition image reconstruction has a time dimension, the objective function is expressed as an equation shown below:

Val=Σ_{f=1}^{N}^{_{f}}∥(G_{f}P_{f}−I)x_{f}∥₂+Σ_{f=1}^{N}^{_{f}}λ·Reg(x_{f})

where x_{f} represents data of an f^{th} two dimensional frame of the second virtual space in parallel acquisition image reconstruction having the time dimension.

In one embodiment, a parallel acquisition image reconstruction device for magnetic resonance imaging is provided, the device may includes:

a data sampling unit, adapted for sampling magnetic resonance signals from a plurality of channels, and filling them in an initial k-space;

a data transformation unit, adapted for performing a mathematical transformation on the initial k-space to obtain a first virtual space;

a channel selection unit, adapted for reserving data of channels of the initial k-space, which have a first parameter higher than a predetermined threshold value, to obtain a second virtual space;

a coefficient calculation unit, adapted for calculating a first combination coefficient from the initial k-space to the second virtual space, and a second combination coefficient from the second virtual space to the initial k-space;

a second virtual space calculation unit, adapted for putting the first combination coefficient and the second combination coefficient, which are obtained by the coefficient calculation unit, into a predetermined objective function to obtain data of the second virtual space; and

an image reconstruction unit, adapted for transforming the data of the second virtual space, which is obtained by the second virtual space calculation unit, into an image domain to obtain a reconstructed image.

Compared with the prior art, the present disclosure has the following advantages: obtaining the first virtual space by performing a mathematical transformation on the initial k-space; and reserving data of channels of the first virtual space, which have a higher signal-to-noise ratio, to serve as the second virtual space by calculating the first parameter of the first virtual space which is used to evaluate signal-to-noise ratio of each channel, whereby the image reconstruction speed is improved and the signal-to-noise ratio of image is improved.

### BRIEF DESCRIPTION OF THE DRAWINGS

FIG. 1 illustrates a schematic diagram of a conventional GRAPPA method for parallel acquisition image reconstruction;

FIG. 2 illustrates a relationship diagram of a conventional GRAPPA method and a conventional SPIRiT method;

FIG. 3 illustrates a schematic flow chart of a parallel acquisition image reconstruction method for magnetic resonance imaging according to one embodiment of the present disclosure;

FIG. 4 illustrates images of all channels in a first virtual space according to one embodiment of the present disclosure;

FIG. 5 illustrates a relationship diagram of channel indexes and eigenvalues in the first virtual space shown in FIG. 4;

FIG. 6 illustrates a schematic diagram of a method for fitting a second virtual space according to one embodiment of the present disclosure; and

FIG. 7 illustrates a schematic structural diagram of a parallel acquisition image reconstruction device for magnetic resonance imaging according to one embodiment of the present disclosure.

### DETAILED DESCRIPTION

In order to make a better understanding of the present disclosure for the persons skilled in the art, a conventional parallel acquisition image reconstruction method for magnetic resonance imaging is briefly described below first.

After filling sampled magnetic resonance signals in k-space, data of k-space can be expressed as Equation (1):

x=D^{T}a+D_{c}^{T}m Equation (1)

where x represents a N*1 vector; a represents a A*1 vector; m represents a M*1 vector; D represents a A*N matrix, which is a sampling matrix of sampled data; and D_{c} represents a M*N matrix, which is a sampling matrix of un-sampled data.

At first, the sampled data D^{T}a of each channel is used to obtain un-sampled data D_{c}^{T}m by fitting. Then data x of the k-space is obtained. The data x of k-space is processed by inverse Fourier transformation and magnitude operation, so as to obtain a magnetic resonance magnitude image. A conventional method for obtaining the un-sampled data D_{c}^{T}m by fitting is described below.

As mentioned above, the GPAPPA method is usually adopted in the prior art. The method includes:

letting: x=GD^{T}a Equation (2)

obtaining: D^{T}a+D_{c}^{T}m=GD^{T}a Equation (3)

obtaining after a transformation: D_{c}^{T}m=(G−I)D^{T}a Equation (4)

where G represents a convolution kernel of the GRAPPA method.

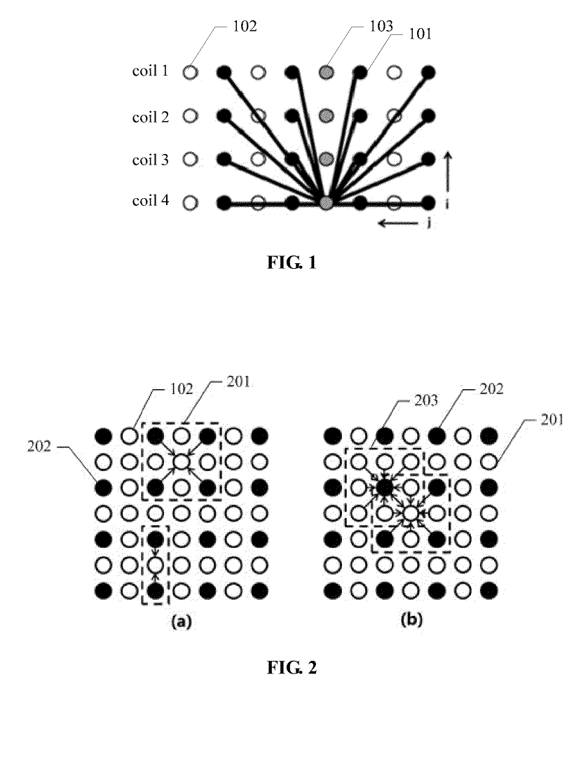

Referring to FIG. 1 and FIG. 2, an un-sampled data D_{c}^{T}m is obtained according to Equation (4) based on a convolution kernel G of each point to be fitted and sampled data D^{T}a around the each point to be fitted.

A SPIRiT method in the prior art is described as below:

letting: x=Kx Equation (5)

obtaining: (K−I)(D^{T}a+D_{c}^{T}m)=0 Equation (6)

obtaining after a transformation: (K−I)D_{c}^{T}m=−(K−I)D^{T}a Equation (7)

where K represents a convolution kernel of the SPIRiT method. As shown in FIG. 2, an un-sampled data D_{c}^{T}m can be obtained according to Equation (7) based on the convolution kernel K of each point to be fitted and sampled data D around the each point to be fitted.

In order to clarify the objects, characteristics and advantages of the disclosure, the embodiments of the present disclosure will be described in detail in conjunction with the accompanying drawings.

### Embodiment 1

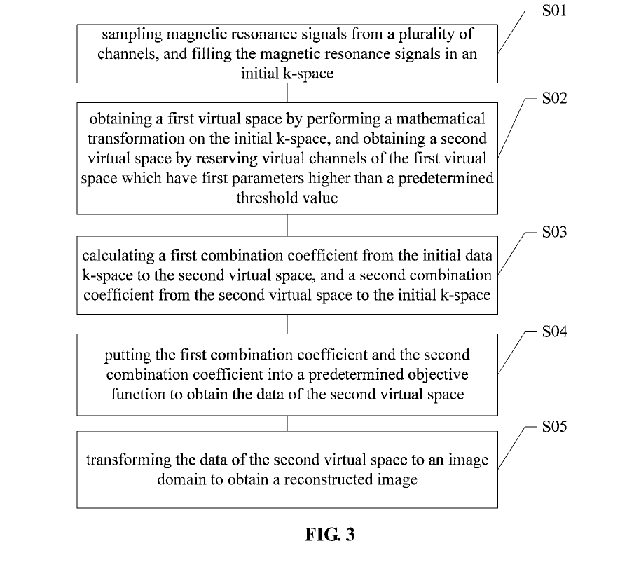

FIG. 3 schematically illustrates a flow chart of a parallel acquisition image reconstruction method for magnetic resonance imaging according to one embodiment. Referring to FIG. 3, the method includes the steps of S01, S02, S03, S04 and S05.

In S01, magnetic resonance signals from a plurality of channels are sampled and the magnetic resonance signals are filled into an initial k-space, where the initial k-space includes a fully-sampled area and an under-sampled area, each data point in the fully-sampled area is sampled, and the under-sampled area includes sampled data points and un-sampled data points.

It should be noted that, in the embodiment, in order to avoid confusion, a space, in which initial magnetic resonance signals (data) obtained from all channels by directly parallel acquisition are filled, is referred to as the initial k-space. Hereinafter, a space, which is obtained by a mathematical transformation on the initial k-space, is referred to as a first virtual space, and a space, which reserves channels of the first virtual space which have a first parameter higher than a predetermined threshold value, is referred to as a second virtual space, where the first parameter is used to evaluate signal-to-noise ratio of each channel.

In one embodiment, the initial k-space x is a [N_{RO}N_{PE}N_{C}] matrix, where N_{C} represents a channel number, and N_{RO} and N_{PE} represent a dimension size of a frequency encoding direction and a dimension size of a phase encoding direction, respectively. In one embodiment, data of the fully-sampled area can be used as calibration data. Therefore, a calibration data matrix may be represented by [Nr_{RO}Nr_{PE}N_{C}], where r represents a calibration data part of the initial k-space.

In S02, a first virtual space is obtained by performing a mathematical transformation on the initial k-space, where the first virtual space comprises a plurality of virtual channels each having a first parameter for evaluating signal-to-noise ratio, and a second virtual space is obtained by reserving virtual channels of the first virtual space which have first parameters higher than a predetermined threshold value.

In one embodiment, a mathematical transformation method, such as Wavelet transformation, Curvelet transformation, Karhunen-Loeve (KL) transformation and etc, may be used obtain a first virtual space. Other embodiments are possible, which is not limited herein. The KL transformation is taken as an example and described in detail below.

The data of the initial k-space is transformed by a KL transformation to obtain the first virtual space. Amplitude of an eigenvalue of the KL transformation of the calibration data of the initial k-space of each channel serves as a first parameter value.

KL transformation is performed on the calibration data part r of the initial k-space to obtain:

r′=r×K Equation (8)

where K represents a N_{C}×N_{C} KL transformation matrix, r′ represents data of the first virtual space after the KL transformation. After the KL transformation, the amplitude of the eigenvalue of K can be used to evaluate a signal-to-noise ratio of a channel of the first virtual space obtained after the mathematical transformation. The higher the eigenvalue, the higher the signal-to-noise ratio. Therefore, after the mathematical transformation, channels having a low signal-to-noise ratio may be eliminated, in order to improve the quality of the reconstructed image.

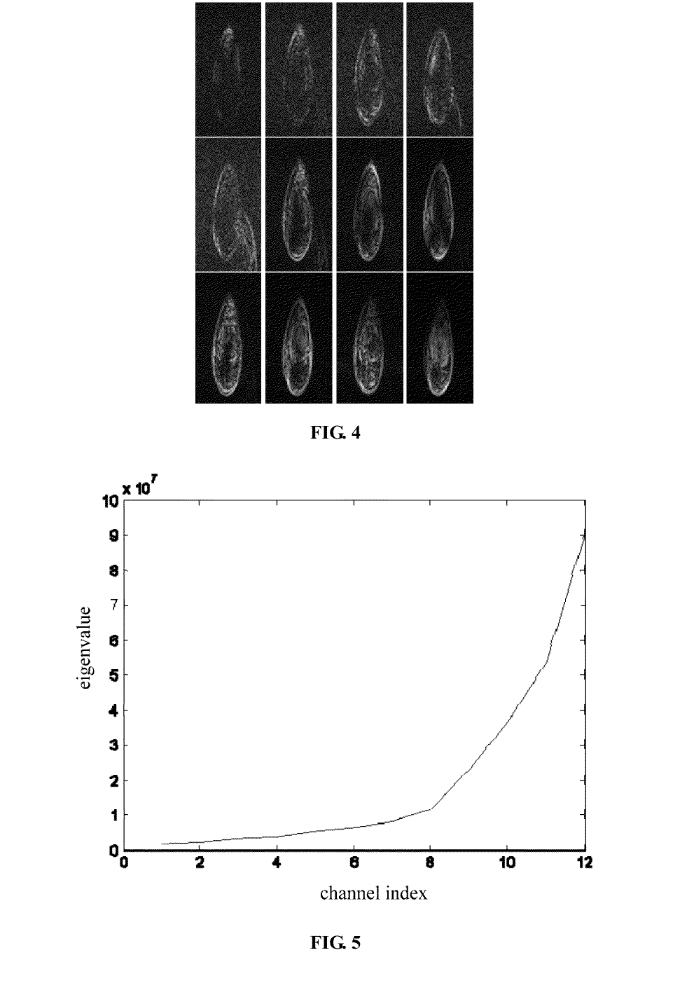

As shown in FIG. 4, images of all channels are obtained after performing the KL transformation on the fully-sampled area of the initial k-space, which is also the calibration data part r. FIG. 5 illustrates a relationship diagram of channel indexes and eigenvalues shown in FIG. 4. Comparison of FIG. 4 and FIG. 5 shows that, the channel having a high eigenvalue has a high signal-to-noise ratio. This rule is also reflected in FIG. 5. In one embodiment, initial data are sampled from twelve channels. After a KL transformation, the first five channels only occupy 1% of total energy. Therefore, the first five channels are abandoned, while the remaining seven channels are used to reconstruct an image. So far, two spaces are established. One is the initial k-space, which is represented by Src, having N_{C} channels. The other is the second k-space, which is represented by Dst, having N_{d} channel, where N_{d}≦N_{C}.

In S03, a first combination coefficient from the initial data k-space to the second virtual space is calculated, and a second combination coefficient from the second virtual space to the initial k-space is calculated.

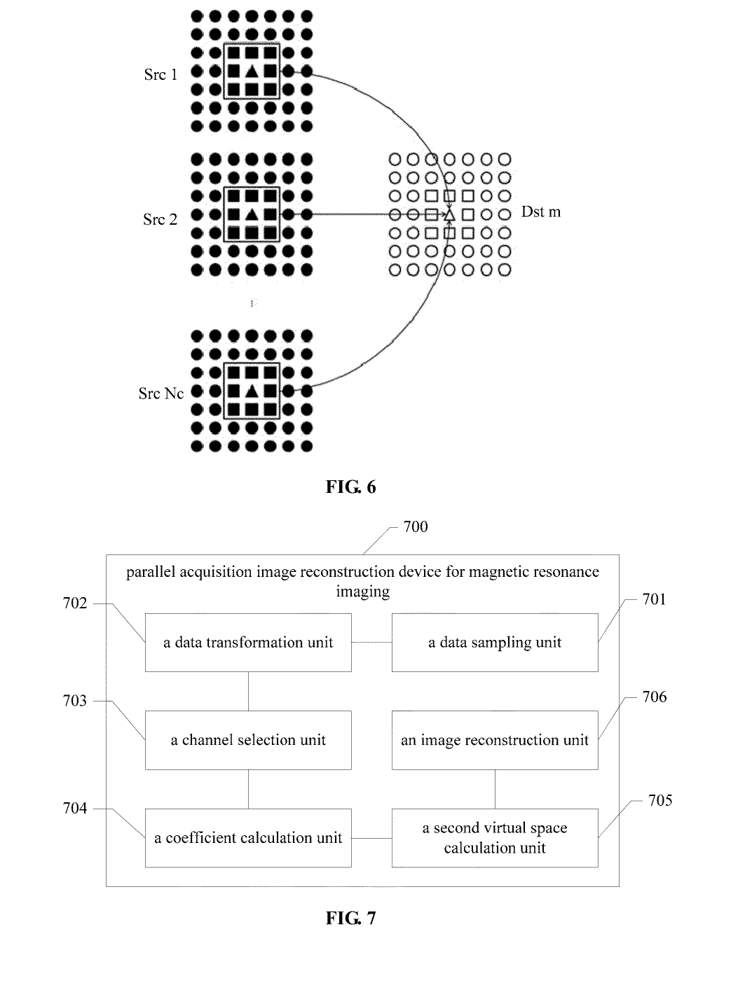

In one embodiment, a process of filling the second virtual space is shown in FIG. 6. Srci (1≦i≦N_{C}) represents data of the i^{th} channel of the initial k-space. Dst m represents data of the m^{th} channel of the second virtual space. Data in a box represents a selected convolution kernel. Solid square points and empty triangular points in the Srci represent selected data points in a fitting operation, which is used to fit the solid square points in the Srci to obtain the empty triangular points in the Dst. The fitting process is shown by an arrow. The fitting process can be expressed as Equation (9):

Src*G=Dst Equation (9)

where Src represents the calibration data of the initial k-space, Dst represents the calibration data of the second virtual space, and G represents a convolution kernel from Src to Dst, which is also the first combination coefficient.

Similarly, a fitting operation may also be performed from Dst to Src, which can be expressed by Equation (10):

Dst*P=Src Equation (10)

where P represents a convolution kernel from Dst to Src, which is also the second combination coefficient.

In S04, the first combination coefficient and the second combination coefficient are put into a predetermined objective function to obtain the data of the second virtual space.

In one embodiment, the predetermined objective function may be expressed as Equation (11):

Val=∥GPx−x∥₂+λ·Reg(x) Equation (11)

where G represents the first combination coefficient, P represents the second combination coefficient, x represents the data of the second virtual space, Reg(x) represents a cost function, λ represents a coefficient of the cost function, and Val represents a target value.

The data x of the second virtual space may be obtained according to Equation (11) under a condition that the target value Val has a minimum value.

In one embodiment, different calculation methods may be adopted in different situations. For example, if the sampled data of the second virtual space is not changed, an objective function (11-1) shown as below may be used to obtain the data x of the second virtual space:

Val=∥(GP−I)(D^{T}a+D_{c}^{T}m)∥₂+λ·∥ψF^{H}(D^{T}a+D_{c}^{T}m)∥₁ Equation (11-1)

where D^{T}a represents sampled data of the second virtual space, D_{c}^{T}m represents un-sampled data of the second virtual space, Ψ represents a regularization transformation matrix, F represents a Fourier transformation, and Val represents a target value. The un-sampled data D_{c}^{T}m of the second virtual space may be obtained according to Equation (11-1) under a condition that the target value Val has a minimum value, and the data x of the second virtual space may be obtained by combining the un-sampled data D_{c}^{T}m and the sampled data D^{T}a of the second virtual space.

When Equation (11-1) is adopted, the regularization transformation matrix needs to be applied to each channel of the second virtual space, resulting in a large time cost. In order to improve image reconstruction speed, a coil sensitivity coefficient is introduced in the calculation. An objective function (11-2) shown as below may be used:

Val=∥(GP−I)(D^{T}a+D_{c}^{T}m)∥₂+λ·∥ψ·S·F^{H}(D^{T}a+D_{c}^{T}m)∥₁ Equation (11-2)

where D^{T}a represents sampled data of the second virtual space, D_{c}^{T}m represents un-sampled data of the second virtual space, Ψ represents a regularization transformation matrix, S represents a coil sensitivity coefficient matrix, F represents a Fourier transformation, and Val represents a target value. The un-sampled data D_{c}^{T}m of the second virtual space may be obtained according to Equation (11-2) under a condition that the target value Val has a minimum value, and the data x of the second virtual space may be obtained by combining the un-sampled data D_{c}^{T}m and the sampled data D^{T}a of the second virtual space.

In one embodiment, a method for obtaining the coil sensitivity coefficient matrix S may include: setting the data of the under-sampled area of the initial k-space to zero (only retaining the calibration data); performing a transformation operation to obtain image domain data Image_i of the multiple channels; combining (e.g., summing, summing of squares, or others) data of the multiple channels to obtain Image_{—}0; and calculating Si=Image_i./Image_{—}0, where “./” represents a division method in a point by point manner, Image_i represents an image of an i^{th} channel, Image_{—}0 represents a total image, and Si represents a coil sensitivity coefficient of the i^{th} channel.

The above is only an example to obtain the coil sensitivity coefficient matrix S. In some embodiments, the coil sensitivity coefficient matrix S may be obtained with other methods.

After the introduction of the coil sensitivity coefficient matrix S, the regularization transformation matrix Ψ only needs to be applied once on an image after channel combination, thereby the image reconstruction speed is improved.

In S05, transforming the data of the second virtual space is transformed to an image domain to obtain a reconstructed image.

In one embodiment, inverse Fourier transformation and magnitude operation are performed on the data of the second virtual space, in order to obtain a magnetic resonance magnitude image. In some embodiments, the step of magnitude operation is optional.

According to embodiments of the present disclosure, the data of the initial k-space is processed by mathematical transformation to serve as the first virtual space, and the channels having high signal-to-noise ratios are reserved to serve as the second virtual space which is used for image reconstruction, in which the number of channels used for image reconstruction is reduced. Therefore, the image reconstruction speed is improved, and the image quality is improved.

In addition, in the process of obtaining the data x of the second virtual space, the regularization transformation matrix Ψ only applied once on the image after channel combination by introducing the coil sensitivity coefficient matrix S. Therefore, time cost is reduced, and the image quality is further improved.

A device corresponding to the method mentioned above for parallel acquisition image reconstruction is provided. FIG. 7 illustrates a schematic structural diagram of the parallel acquisition image reconstruction device for magnetic resonance imaging. In one embodiment, the device includes:

a data sampling unit 701, adapted for sampling magnetic resonance signals from a plurality of channels, and filling them in an initial k-space;

a data transformation unit 702, adapted for performing a mathematical transformation on the initial k-space to obtain a first virtual space;

a channel selection unit 703, adapted for reserving data of channels of the initial k-space, which have a first parameter higher than a predetermined threshold value, to obtain a second virtual space;

a coefficient calculation unit 704, adapted for calculating a first combination coefficient from the initial k-space to the second virtual space, and a second combination coefficient from the second virtual space to the initial k-space;

a second virtual space calculation unit 705, adapted for putting the first combination coefficient and the second combination coefficient, which are obtained by the coefficient calculation unit 704, into a predetermined objective function to obtain data of the second virtual space; and

an image reconstruction unit 706, adapted for transforming the data of the second virtual space, which is obtained by the second virtual space calculation unit 705, into an image domain to obtain a reconstructed image.

In one embodiment, a Wavelet transformation, a Curvelet transformation, a Karhunen-Loeve (KL) transformation or other mathematical transformation methods may be used by the data transformation unit 702 to transform the data of the initial k-space to the first virtual space.

### Embodiment 2

In the above embodiments, the sampled data is not changed in the process of calculating the objective function.

In some embodiments, the sampled data may be changed in the process of calculating the objective function, which means each data point of the second virtual space is assumed to be unknown. Then the data x of the second virtual space may be obtained according to an objective function (11-3) shown as below:

Val=∥(GP−I)x∥₂+λ·∥ψF^{H}x∥₁+β·∥Dx−a∥₂ Equation (11-3)

where x represents the data of the second virtual space, Ψ represents a regularization transformation matrix, F represents a Fourier transformation, β represents an adjustment coefficient, D represents a sampling matrix of the sampled data, and Val represents a target value. And the data x of the second virtual space may be obtained according to Equation (11-3) under a condition that the target value Val has a minimum value.

Similarly, a coil sensitivity coefficient may be introduced into Equation (11-3), in order to further improve imaging speed. Specifically, the data x of the second virtual space may be obtained according to an objective function (11-4) shown as below:

Val=∥(GP−I)x∥₂+λ·∥ψ·S·F^{H}x∥₁+β·∥Dx−a∥₂ Equation (11-4)

where x represents the data of the second virtual space, Ψ represents a regularization transformation matrix, S represents a coil sensitivity coefficient matrix, F represents a Fourier transformation, D represents a sampling matrix of sampled data, β represents an adjustment coefficient, and Val represents a target value. The data x of the second virtual space may be obtained according to Equation (11-4) under a condition that the target value Val has a minimum value.

### Embodiment 3

The method according to embodiments of the present disclosure may be used in parallel acquisition image reconstruction in which a time dimension is introduced. For an f^{th} two dimension (2D) frame, data of the second virtual space may be expressed as Equation (12):

x_{f}=D^{T}a_{f}+D_{c}^{T}m_{f} Equation (12)

where x_{f} represents the f^{th} frame data of the second virtual space.

In the process of reconstructing a 2D frame at time T, all x_{f} is combined to form a great vector according to Equation (13):

∥(GP−I)x∥₂=Σ_{f=1}^{N}^{_{f}}∥(G_{f}P_{f}−I)x_{f}∥₂ Equation (13)

By putting Equation (12) or Equation (13) to Equation (11) or any one of Equations from (11-1) to (11-4), an objective function for calculating data x of the second virtual space is obtained in parallel acquisition image reconstruction having a time dimension.

For example, by putting Equation (13) into Equation (11), an objective function for calculating the data x_{f} of the second virtual space, which has a time dimension, is obtained as below:

Val=Σ_{f=1}^{N}^{_{f}}∥(G_{f}P_{f}−I)x_{f}∥₂+Σ_{f=1}^{N}^{_{f}}λ·Reg(x_{f}) Equation (11-5)

Embodiments of the present disclosure are described in a progressive way. Differences between the embodiments are described in detail, while similar parts of the hereafter mentioned embodiments may refer to the aforementioned embodiments, for the sake of clarity.

Although the present disclosure has been disclosed above with reference to preferred embodiments thereof, it should be understood that the disclosure is presented by way of example only, and not limitation. Those skilled in the art can modify and vary the embodiments without departing from the spirit and scope of the present disclosure.

What is claimed is:

1. A parallel acquisition image reconstruction method for magnetic resonance imaging, comprising:
sampling magnetic resonance signals from a plurality of channels, and filling the magnetic resonance signals in an initial k-space, where the initial k-space comprises a fully-sampled area and an under-sampled area, each data point in the fully-sampled area is sampled, and the under-sampled area comprises sampled data points and un-sampled data points;
obtaining a first virtual space by performing a mathematical transformation on the initial k-space, where the first virtual space comprises a plurality of virtual channels each having a first parameter for evaluating signal-to-noise ratio, and obtaining a second virtual space by reserving virtual channels of the first virtual space which have first parameters higher than a predetermined threshold value;
calculating a first combination coefficient from the data of the initial k-space to data of the second virtual space, and a second combination coefficient from the data of the second virtual space to the data of the initial k-space;
putting the first combination coefficient and the second combination coefficient into a predetermined objective function to obtain the data of the second virtual space; and
transforming the data of the second virtual space to an image domain to obtain a reconstructed image.

2. The method according to claim 1, wherein the mathematical transformation comprises: Wavelet transformation, Curvelet transformation or Karhunen-Loeve (KL) transformation.

3. The method according to claim 2, wherein the Karhunen-Loeve transformation is adopted to obtain the first virtual space; data of the fully-sampled area serves as calibration data, and the first parameter is amplitude of an eigenvalue of the KL transformation of the calibration data of each channel.

4. The method according to claim 1, wherein the first combination coefficient is a convolution kernel of a fitting operation from the initial k-space to the second virtual space of each channel, where the first combination coefficient is obtained according to an equation shown below:
Src*G=Dst,
where Src represents the data of the initial k-space of each channel, Dst represents the data of the second virtual space, and G represents the first combination coefficient;
the second combination coefficient is a convolution kernel of a fitting operation from the second virtual space to the initial k-space of each channel, where the second combination coefficient is obtained according to an equation shown below:
Dst*P=Src,
where P represents the second combination coefficient.

5. The method according to claim 1, wherein the objective function is expressed as an equation shown below:
Val=∥GPx−x∥₂+λ·Reg(x)
where G represents the first combination coefficient, P represents the second combination coefficient, x represents the data of the second virtual space, Reg(x) represents a cost function, λ represents a coefficient of the cost function, Val represents a target value, and the data x of the second virtual space is obtained according to the objective function under a condition that the target value Val has a minimum value.

6. The method according to claim 5, wherein the objective function is expressed as an equation shown below:
Val=∥(GP−I)(D^{T}a+D_{c}^{T}m)∥₂+λ·∥ψF^{H}(D^{T}a+D_{c}^{T}m)∥₁
where D^{T}a represents sampled data of the second virtual space, D_{c}^{T}m represents un-sampled data of the second virtual space, Ψ represents a regularization transformation matrix, F represents a Fourier transformation, Val represents a target value, the un-sampled data D_{c}^{T}m of the second virtual space is obtained according to the objective function under a condition that the target value Val has a minimum value, and the data x of the second virtual space is obtained by combining the un-sampled data D_{c}^{T}m and the sampled data D^{T}a of the second virtual space.

7. The method according to claim 5, wherein the objective function is expressed as an equation shown below:
Val=∥(GP−I)(D^{T}a+D_{c}^{T}m)∥₂+λ·∥ψ·S·F^{H}(D^{T}a+D_{c}^{T}m)∥₁
where D^{T}a represents sampled data of the second virtual space, D_{c}^{T}m represents un-sampled data of the second virtual space, Ψ represents a regularization transformation matrix, S represents a coil sensitivity coefficient matrix, F represents a Fourier transformation, Val represents a target value, the un-sampled data D_{c}^{T}m of the second virtual space is obtained according to the objective function under a condition that the target value Val has a minimum value, and the data x of the second virtual space is obtained by combining the un-sampled data D_{c}^{T}m and the sampled data D^{T}a of the second virtual space.

8. The method according to claim 5, wherein assuming that each data point of the second virtual space is unknown, the objective function is expressed as an equation shown below:
Val=∥(GP−I)x∥₂+λ·∥ψF^{H}x∥₁+β·∥Dx−a∥₂
where x represents the data of the second virtual space, Ψ represents a regularization transformation matrix, F represents a Fourier transformation, D represents a sampling matrix of sampled data, β represents an adjustment coefficient, Val represents a target value, and the data x of the second virtual space is obtained according to the objective function under a condition that the target value Val has a minimum value.

9. The method according to claim 5, wherein assuming that each data point of the second virtual space is unknown, the objective function is expressed as an equation shown below:
Val=∥(GP−I)x∥₂+λ·∥ψ·S·F^{H}x∥₁+β·∥Dx−a∥₂
where x represents the data of the second virtual space, Ψ represents a regularization transformation matrix, S represents a coil sensitivity coefficient matrix, F represents a Fourier transformation, D represents a sampling matrix of sampled data, β represents an adjustment coefficient, Val represents a target value, and the data x of the second virtual space is obtained according to the objective function under a condition that the target value Val has a minimum value.

10. The method according to claim 5, wherein if the parallel acquisition image reconstruction has a time dimension, the objective function is expressed as an equation shown below:
Val=Σ_{f=1}^{N}^{_{f}}∥(G_{f}P_{f}−I)x_{f}∥₂+Σ_{f=1}^{N}^{_{f}}λ·Reg(x_{f})
where x_{f} represents data of an f^{th} two dimensional frame of the second virtual space in parallel acquisition image reconstruction having the time dimension.

11. A parallel acquisition image reconstruction device for magnetic resonance imaging, comprising:
a data sampling unit, adapted for sampling magnetic resonance signals from a plurality of channels, and filling them in an initial k-space;
a data transformation unit, adapted for performing a mathematical transformation on the initial k-space to obtain a first virtual space;
a channel selection unit, adapted for reserving data of channels of the initial k-space, which have a first parameter higher than a predetermined threshold value, to obtain a second virtual space;
a coefficient calculation unit, adapted for calculating a first combination coefficient from the initial k-space to the second virtual space, and a second combination coefficient from the second virtual space to the initial k-space;
a second virtual space calculation unit, adapted for putting the first combination coefficient and the second combination coefficient, which are obtained by the coefficient calculation unit, into a predetermined objective function to obtain data of the second virtual space; and
an image reconstruction unit, adapted for transforming the data of the second virtual space, which is obtained by the second virtual space calculation unit, into an image domain to obtain a reconstructed image.
